(19) United States
(12) Patent Application Publication
(10) Pub. No.: US 2023/0276616 A1
(43) Pub. Date: Aug. 31, 2023

(54) SEMICONDUCTOR STRUCTURE AND SEMICONDUCTOR MANUFACTURING METHOD

(71) Applicant: NANYA TECHNOLOGY CORPORATION, New Taipei City (TW)

(72) Inventors: Yu-Ying LIN, Tainan City (TW); Chung-Lin HUANG, Taoyuan City (TW)

(21) Appl. No.: 17/652,486

(22) Filed: Feb. 25, 2022

(51) Int. Cl. H01L 27/108

(52) U.S. Cl. CPC H01L 27/10885; H01L 27/10814; H01L 27/10855

(57) ABSTRACT

A semiconductor structure includes a semiconductor substrate; a spacer located in a trench of the semiconductor substrate, wherein the spacer includes two trench nitride layers and an empty gap sandwiched between the two trench nitride layers; a first nitride layer disposed to seal an exposed opening of the empty gap between the two trench nitride layers; a second nitride layer over the first nitride layer, wherein the second nitride layer has a higher density than the first nitride layer; and a third nitride layer having a first portion over the second nitride layer and a second portion disposed on sidewalls of the two trench nitride layers.

### BACKGROUND

### Field of Disclosure

The present disclosure relates to semiconductor structures and semiconductor manufacturing methods.

### Description of Related Art

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed. For example, aggressive scaling down of IC dimensions has resulted in increased parasitic capacitance (e.g., between a bit line and a cell container contact). As a result of such increased parasitic capacitance, device performance is degraded. Thus, existing techniques have not proved entirely satisfactory in all respects.

### SUMMARY

The present disclosure provides semiconductor structures and semiconductor manufacturing methods to deal with the needs of the prior art problems.

In one or more embodiments, a semiconductor manufacturing method includes the following steps: providing a semiconductor substrate; forming a spacer disposed in a trench of the semiconductor substrate, wherein the spacer comprises an oxide layer sandwiched between two trench nitride layers; forming a first nitride layer to seal an exposed opening of the empty gap between the two trench nitride layers; forming a second nitride layer over the first nitride layer, wherein the second nitride layer has a higher density than the first nitride layer; and using an atomic layer deposition to form a third nitride layer over the second nitride layer, wherein at least part of the third nitride layer diffuses through the first and second nitride layers to be disposed on sidewalls of the two trench nitride layers.

In one or more embodiments, the third nitride layer has a higher density than the first nitride layer.

In one or more embodiments, the third nitride layer has a higher density than the second nitride layer.

In one or more embodiments, the at least part of the third nitride layer disposed on sidewalls of the two trench nitride layers forms a thin film having a thickness ranging from 1 nm to 2 nm.

In one or more embodiments, the first nitride layer is deposited at a faster rate than the second nitride layer.

In one or more embodiments, the third nitride layer is deposited at a slower rate than the first nitride layer.

In one or more embodiments, the third nitride layer is deposited at a slower rate than the second nitride layer.

In one or more embodiments, the first nitride layer has a hydrofluoric acid etching rate higher than that of the second nitride layer.

In one or more embodiments, the first nitride layer has a hydrofluoric acid etching rate higher than that of the third nitride layer.

In one or more embodiments, the second nitride layer has a hydrofluoric acid etching rate higher than that of the third nitride layer.

In one or more embodiments, a semiconductor manufacturing method includes the following steps: providing a semiconductor substrate; forming a cell container contact in the semiconductor substrate; forming a bit line structure in the semiconductor substrate; forming a bit line structure in the semiconductor substrate; forming a spacer disposed in a trench of the semiconductor substrate, wherein the spacer is sandwiched between the cell container contact and the bit line structure, the spacer comprises two trench nitride layers and an oxide layer sandwiched between the two trench nitride layers; etching the oxide layer to form an empty gap between the two trench nitride layers; forming a first nitride layer to seal an exposed opening of the empty gap between the two trench nitride layers; forming a second nitride layer over the first nitride layer, wherein the second nitride layer has a higher density than the first nitride layer; and using an atomic layer deposition to form a third nitride layer over the second nitride layer, wherein at least part of the third nitride layer diffuses through the first and second nitride layers to be disposed on sidewalls of the two trench nitride layers.

In one or more embodiments, the bit line structure comprises a bit line cap, a bit line contact and a bit line between the bit line cap dielectric and the bit line contact.

In one or more embodiments, the method further includes forming a landing pad partially embedded in the cell container contact.

In one or more embodiments, the third nitride layer has a higher density than the first nitride layer or the second nitride layer.

In one or more embodiments, the at least part of the third nitride layer disposed on sidewalls of the two trench nitride layers forms a thin film having a thickness ranging from 1 nm to 2 nm.

In one or more embodiments, the controller is configured to generate the second burn-in board status map of the suspended burn-in board according to tested results of the qualified-passed integrated circuit devices.

In one or more embodiments, the third nitride layer is deposited at a slower rate than the first nitride layer or the second nitride layer.

In one or more embodiments, the first nitride layer has a hydrofluoric acid etching rate higher than that of the second nitride layer.

In one or more embodiments, the second nitride layer has a hydrofluoric acid etching rate higher than that of the third nitride layer.

In one or more embodiments, a semiconductor structure includes a semiconductor substrate; a spacer located in a trench of the semiconductor substrate, wherein the spacer includes two trench nitride layers and an empty gap sandwiched between the two trench nitride layers; a first nitride layer disposed to seal an exposed opening of the empty gap between the two trench nitride layers; a second nitride layer over the first nitride layer, wherein the second nitride layer has a higher density than the first nitride layer; and a third nitride layer having a first portion over the second nitride layer and a second portion disposed on sidewalls of the two trench nitride layers.

In one or more embodiments, the first portion and the second portion of the third nitride layer have the same density.

In sum, the semiconductor structure disclosed herein has its bit line spacer including two trench nitride layers sandwiching an empty gap. Etching damages of the two trench nitride layers are repaired by an atomic layer deposition of nitride layer so as to reduce the current leakage from the bit line structure to the cell container contact and the cell container. A first nitride layer is configured to seal an opening of the empty gap. A second nitride layer over the first nitride layer is configured to control a diffuse amount of the atomic layer deposition of nitride layer. The empty gap between the two trench nitride layers lower the dielectric constant of the bit line spacer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1, 2A, 3, 4 and 5 illustrate cross sections of semiconductor manufacturing steps according to some embodiments of the present disclosure;

FIG. 2B illustrates a top view associated with FIG. 2A; and

FIG. 6 illustrates a flow chart of a semiconductor manufacturing method according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

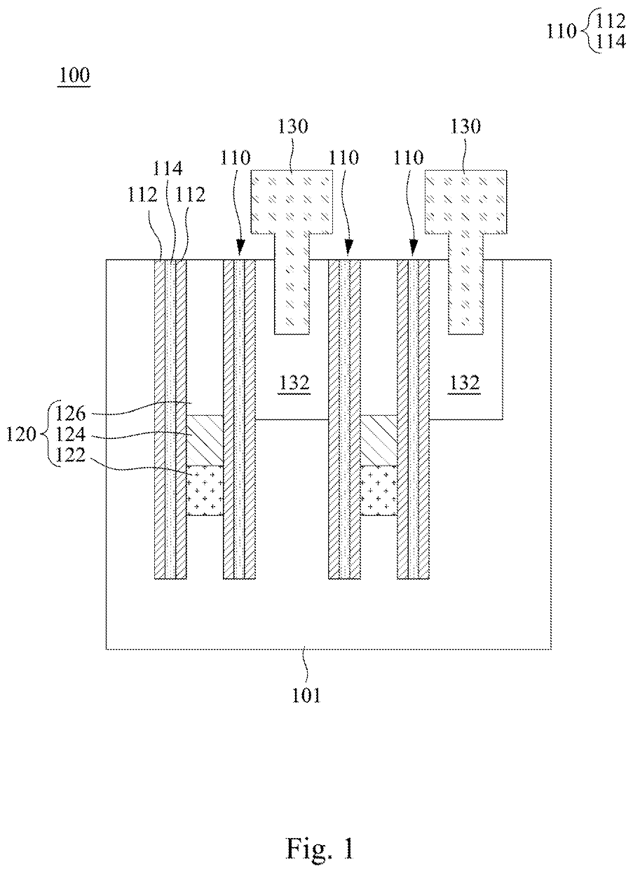

Reference is made to FIG. 1, which a cross sectional view of a first semiconductor manufacturing step according to some embodiments of the present disclosure. A semiconductor structure 100 includes a semiconductor substrate 101 and a memory associated structure inside. In particular, a bit line structure 120 is formed in the semiconductor substrate 101. The bit line structure 120 includes a bit line contact 122, a bit line 124 and a bit line cap dielectric 126. The bit line 124 is sandwiched between the bit line contact 122 and the bit line cap dielectric 126. There are two spacers 110 located on two opposite sides of the bit line structure 120. A cell container contact 132 is located between two adjacent spacers 110. In other words, each spacer 110 is sandwiched between the cell container contact 132 and the bit line structure 120. A land pad 130 is also formed in contact with the cell container contact 132.

In some embodiments of the present disclosure, the substrate 101 may be a semiconductor substrate, such as a bulk semiconductor, a semiconductor-on-insulator (SOI) substrate, or the like, which may be doped (e.g., with a p-type or an n-type dopant) or undoped. The substrate 101 may be an integrated circuit die, such as a logic die, a memory die, an ASIC die, or the like. The substrate 101 may be a complementary metal oxide semiconductor (CMOS) die and may be referred to as a CMOS under array (CUA). The substrate 101 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate.

In some embodiments of the present disclosure, the bit line 124 may include one or more layers, such as glue layers, barrier layers, diffusion layers, and fill layers, and the like and may be formed using metals and/or metal alloys such as aluminum (Al), titanium (Ti), titanium nitride (TiN), tantalum nitride (TaN), cobalt (Co), silver (Ag), gold (Au), copper (Cu), nickel (Ni), chromium (Cr), hafnium (Hf), ruthenium (Ru), tungsten (W), platinum (Pt), alloys thereof, or the like.

In some embodiments of the present disclosure, the bit line contact 122 may include may be formed using polysilicon, metals and/or metal alloys such as aluminum (Al), titanium (Ti), titanium nitride (TiN), tantalum nitride (TaN), cobalt (Co), silver (Ag), gold (Au), copper (Cu), nickel (Ni), chromium (Cr), hafnium (Hf), ruthenium (Ru), tungsten (W), platinum (Pt), alloys thereof, or the like.

In some embodiments of the present disclosure, the cell container contact 132 may include may be formed using polysilicon, metals and/or metal alloys such as aluminum (Al), titanium (Ti), titanium nitride (TiN), tantalum nitride (TaN), cobalt (Co), silver (Ag), gold (Au), copper (Cu), nickel (Ni), chromium (Cr), hafnium (Hf), ruthenium (Ru), tungsten (W), platinum (Pt), alloys thereof, or the like.

In some embodiments of the present disclosure, each spacer 110 is a dielectric multi-layer structure in a trench of the semiconductor substrate 101. Each multi-layer structure includes two trench nitride layers 112 (e.g., two silicon nitride layers) and an oxide layer 114 (e.g., a silicon oxide layer) sandwiched between two the trench nitride layers 112. The oxide layer 114 is in contact with two trench nitride layers 112 at two opposite sides. Due to the each spacer 110, a parasitic capacitance is formed between the cell container contact 132 and the bit line structure 120.

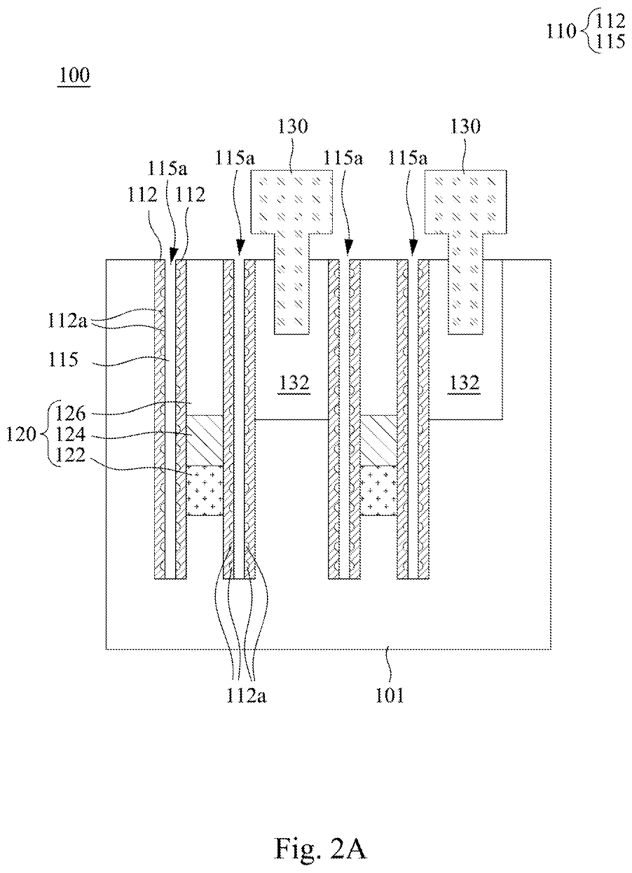

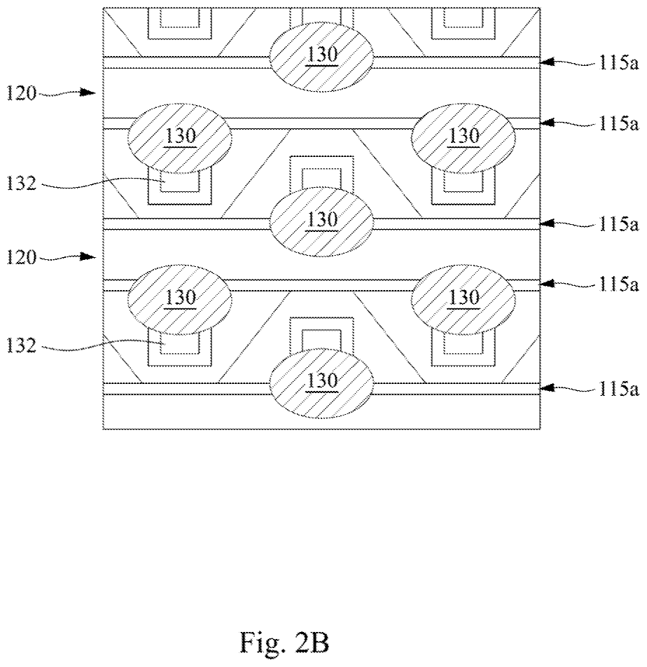

Reference is made to FIGS. 2A and 2B, FIG. 2A illustrates a cross sectional view of a second semiconductor manufacturing step according to some embodiments of the present disclosure, and FIG. 2B illustrates a top view associated with FIG. 2A. In order to reduce the parasitic capacitance between the cell container contact 132 and the bit line structure 120, a dielectric constant of the spacer 110 needs to be reduced. Thus, a suitable etch process step, e.g., a chemical oxide removal process, is used to etch the oxide layer 114 between two trench nitride layers 112 to form an empty gap 115 (e.g., an air gap) between two trench nitride layers 112 so as to decrease the dielectric constant of the spacer 110. During the etch process step, the two trench nitride layers 112 may have inevitable damages 112a (e.g., small cavities on sidewalls of each nitride layer). Due to the damages 112a of the trench nitride layers 112, a current leakage (e.g., along the arrows) between the between the cell container contact 132 and the bit line structure 120 will rise, and electrical properties of electronic components, e.g., a memory device, will be deteriorated as a result.

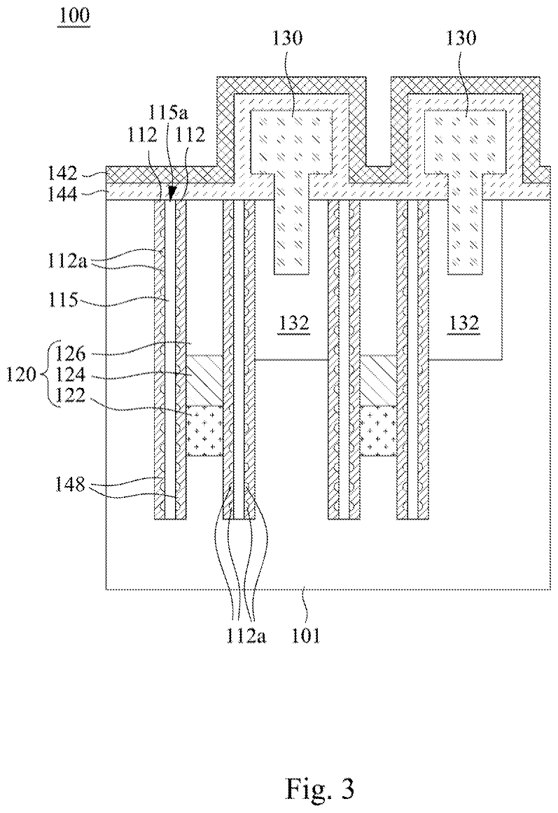

Reference is made to FIG. 3, which illustrates a cross sectional view of a third semiconductor manufacturing step according to some embodiments of the present disclosure. A first nitride layer 144 is deposited by a suitable process, e.g., a plasma enhanced chemical vapor deposition (PECVD) process, to seal an exposed opening 115a of the empty gap 115 between the two trench nitride layers 112. The first nitride layer 144 is a “loose” nitride layer which is deposited to cover the opening 115a of the empty gap 115 between the two trench nitride layers 112, and no nitride layer will be deposited into the empty gap 115 (e.g., an air gap) between the two trench nitride layers 112. A second nitride layer 142 is deposited by a suitable process, e.g., a plasma enhanced chemical vapor deposition (PECVD) process, to cover the first nitride layer 144. Since the first nitride layer 144 has sealed the opening 115a of the empty gap 115, the second nitride layer 142 is still not deposited into the empty gap 115 (e.g., an air gap) between the two trench nitride layers 112. The second nitride layer 142 is “denser” than the first nitride layer 144 is. In some embodiments of the present disclosure, the second nitride layer 142 has a higher density than the first nitride layer 144 has.

In some embodiments of the present disclosure, the first nitride layer 144 is deposited at a faster rate than the second nitride layer 142, e.g., the first nitride layer 144 is deposited at 31 Å/sec, and the second nitride layer 142 is deposited at 17 Å/sec. In some embodiments of the present disclosure, the first nitride layer 144 and the second nitride layer 142 are deposited at about the same temperature, e.g., 500° C. In some embodiments of the present disclosure, the first nitride layer 144 is deposited under a pressure higher than a pressure under which the second nitride layer 142 is deposited. In some embodiments of the present disclosure, the first nitride layer 144 has a hydrofluoric acid etching rate (e.g., 300 Å/min) higher than a hydrofluoric acid etching rate (e.g., 170 Å/min) of the second nitride layer 142. In some embodiments of the present disclosure, the first nitride layer 144 has a thickness ranging from about 10 nanometers to about 50 nanometers, and the second nitride layer 142 has a thickness ranging from about 10 nanometers to about 50 nanometers.

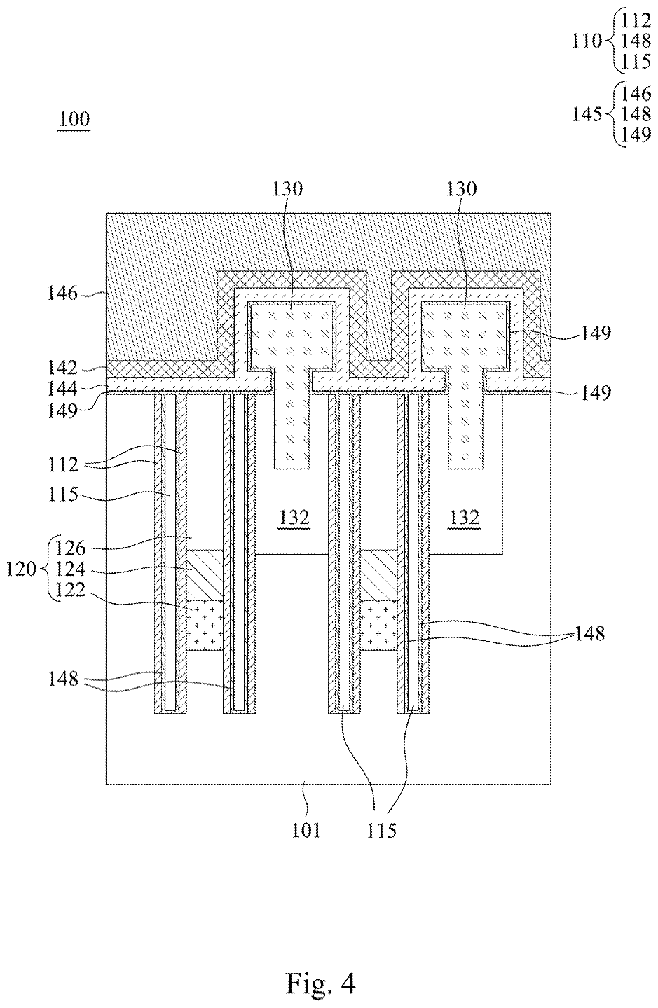

Reference is made to FIG. 4, which illustrates a cross sectional view of a fourth semiconductor manufacturing step according to some embodiments of the present disclosure. A third nitride layer 145 is deposited by an atomic layer deposition to cover the second nitride layer 142. Since the first nitride layer 144 and the second nitride layer 142 are “relatively loose” to the atomic layer deposition, at least some part of the third nitride layer 145 may diffuse through the first nitride layer 144 and the second nitride layer 142 and into the empty gap 115 between the two trench nitride layers 112, at least part of the third nitride layer 145 diffuses through the first nitride layer 144 and the second nitride layer 142 to be located on sidewalls of the two trench nitride layers 122 to repair the damages 112a on sidewalls of the trench nitride layers 112 (e.g., to fill small cavities on sidewalls of the trench nitride layers 112), and other regions under the first nitride layer 144 and the second nitride layer 142. In particular, a nitride thin film 148 (e.g., a silicon nitride thin film) is formed on sidewalls of the two trench nitride layers 122 and has a thickness ranging from 1 nanometer to 2 nanometers. That is, the third nitride layer may has a first portion 146 over the second nitride layer 142, a second portion 148 (e.g., the nitride thin film) on sidewalls of the two trench nitride layers 122 and other remaining portions 149 over other regions under the first nitride layer 144 and the second nitride layer 142. In some embodiments of the present disclosure, the second portion 148 of the third nitride layer 145 may fully enclose the empty gap 115 therein. In some embodiments of the present disclosure, the first portion 146 and the second portion 148 of the third nitride layer 145 have the same density because these two portions are made by the same atomic layer deposition step. In some embodiments of the present disclosure, the first portion 146 and the second portion 148 of the third nitride layer 145 have substantially the same hydrofluoric acid etching rate because these two portions are made by the same atomic layer deposition step. In some embodiments of the present disclosure, the first portion 146 of the third nitride layer 145 has a thickness ranging from about 10 nanometers to about 50 nanometers. With the damages 112a of the trench nitride layers 112 being repaired by the atomic layer deposition of nitride layer, the repaired trench nitride layers 112 will reduce the current leakage between the between the cell container contact 132 and the bit line structure 120, and the empty gap 115 still lowers the dielectric constant of the spacer 110 so as to enhance electrical properties of electronic components, e.g., a memory device.

In some embodiments of the present disclosure, the first nitride layer 144 is deposited with a faster rate and “loose” enough such that the first nitride layer 144 can seal the opening 115a of the empty gap 115 without being deposited into the empty gap 115. In some embodiments of the present disclosure, the first nitride layer 144 also prevents the second nitride layer 142 from being deposited into the empty gap 115. In some embodiments of the present disclosure, the second nitride layer 142 is deposited with a slower rate than the first nitride layer 144 to have a denser nitride layer which is utilized to control a diffuse amount of the atomic layer deposition for the third nitride layer 145.

In some embodiments of the present disclosure, the third nitride layer 145 has a higher density than the first nitride layer 144 and the second nitride layer 142. In some embodiments of the present disclosure, the third nitride layer 145 is deposited at a slower rate (e.g., 6 Å/sec) than the first nitride layer 144 and the second nitride layer 142, e.g., the first nitride layer 144 is deposited at 31 Å/sec, and the second nitride layer 142 is deposited at 17 Å/sec. In some embodiments of the present disclosure, the third nitride layer 145 is deposited at a higher temperature, e.g., 550° C. than the first nitride layer 144 and the second nitride layer 142 are deposited, e.g., 500° C. In some embodiments of the present disclosure, the first nitride layer 144 has a hydrofluoric acid etching rate (e.g., 300 Å/min) higher than a hydrofluoric acid etching rate (e.g., 6 Å/min) of the third nitride layer 145. In some embodiments of the present disclosure, the second nitride layer 142 has a hydrofluoric acid etching rate (e.g., 170 Å/min) higher than a hydrofluoric acid etching rate (e.g., 6 Å/min) of the third nitride layer 145.

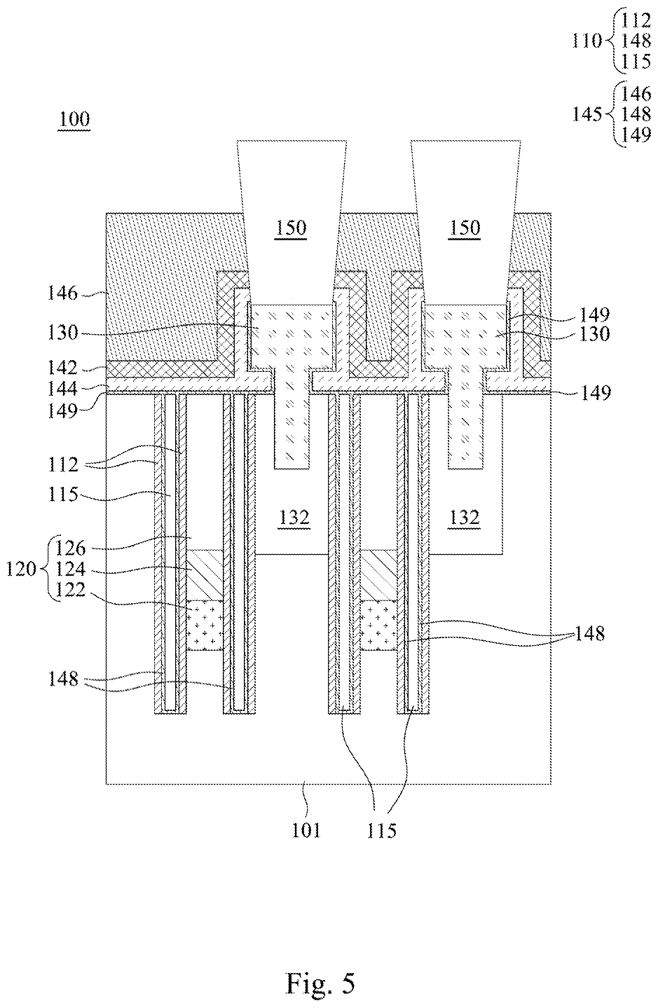

Reference is made to FIG. 5, which illustrates a cross sectional view of a fifth semiconductor manufacturing step according to some embodiments of the present disclosure. A cell container 150 is formed with its bottom in contact with a top surface of the land pad 130. An etching process is utilized to form a recess through the first nitride layer 144, the second nitride layer 142 and the first portion 146 of the third nitride layer 145 to expose the top surface of the land pad 130 such that the cell container 150 can be deposited in the recess. The cell container 150 may include a storage layer and a channel layer. In some embodiments of the present disclosure, the storage layer may be formed of a composite layer including a silicon oxide layer, a silicon nitride layer, and a silicon oxide layer (i.e., an ONO layer stack). However, the structure of the storage layer is not limited to this regard. In some other embodiments, the storage layer may be selected from a group consisting of an oxide-nitride-oxide-nitride-oxide (ONONO) structure, a silicon-oxide-nitride-oxide-silicon (SONOS) structure, a bandgap engineered silicon-oxide-nitride-oxide-silicon (BE-SONOS) structure, a tantalum nitride-aluminum oxide-silicon nitride-silicon oxide-silicon (TANOS) structure and a metal-high-k bandgap-engineered silicon-oxide-nitride-oxide-silicon (MA BE-SONOS) structure. In the present embodiment, the storage layer includes an ONO structure and the channel layer is made of poly-silicon.

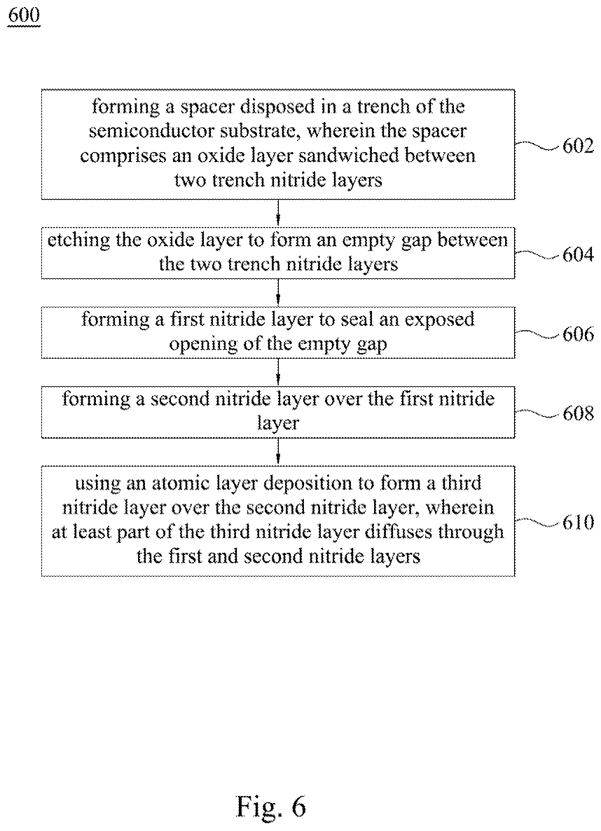

Reference is made to FIG. 6, which illustrates a flow chart of a semiconductor manufacturing method 600 according to some embodiments of the present disclosure. In step 602 (also referring to FIG. 1), a plurality of spacers 110 are formed in trenches of a semiconductor substrate 101. Each spacer 110 includes two trench nitride layers 112 and an oxide layer 114 sandwiched between the two trench nitride layers 112. In step 604 (also referring to FIG. 2A), the oxide layer 114 is etched to form an empty gap between the two trench nitride layers 112 in order to lower a dielectric constant of the spacer 110. In step 606 (also referring to FIG. 3), a first nitride layer 144 is deposited by a suitable process, e.g., a plasma enhanced chemical vapor deposition (PECVD) process, to seal an exposed opening 115a of the empty gap 115 between the two trench nitride layers 112. In step 608 (also referring to FIG. 3), a second nitride layer 142 is deposited by a suitable process, e.g., a plasma enhanced chemical vapor deposition (PECVD) process, to cover the first nitride layer 144. In step 610 (also referring to FIG. 4), a third nitride layer 145 is deposited by an atomic layer deposition to cover the second nitride layer 142, wherein at least part (e.g., a second portion 148) of the third nitride layer 145 diffuses through the first nitride layer 144 and second nitride layer 142 and into the empty gap 115 to be coated on sidewalls of the two trench nitride layers 112. In step 604, etching the oxide layer 114 would inevitably cause damages 112a (e.g., small cavities) on sidewalls of the nitride layers 112. The atomic layer deposition of the third nitride layer 145 is configured to repair the damages 112a on sidewalls of the nitride layers 112.

In sum, the semiconductor structure disclosed herein has its bit line spacer including two trench nitride layers sandwiching an empty gap. Etching damages of the two trench nitride layers are repaired by an atomic layer deposition of nitride layer so as to reduce the current leakage from the bit line structure to the cell container contact and the cell container. A first nitride layer is configured to seal an opening of the empty gap. A second nitride layer over the first nitride layer is configured to control a diffuse amount of the atomic layer deposition of nitride layer. The empty gap between the two trench nitride layers lower the dielectric constant of the bit line spacer.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor manufacturing method comprising:
providing a semiconductor substrate;
forming a spacer disposed in a trench of the semiconductor substrate, wherein the spacer comprises two trench nitride layers and an oxide layer sandwiched between the two trench nitride layers;
etching the oxide layer to form an empty gap between the two trench nitride layers;
forming a first nitride layer to cover the empty gap between the two trench nitride layers;
forming a second nitride layer over the first nitride layer, wherein the second nitride layer has a higher density than the first nitride layer; and
using an atomic layer deposition to form a third nitride layer over the second nitride layer, wherein at least part of the third nitride layer diffuses through the first and second nitride layers into the empty gap.

2. The method of claim 1, wherein the third nitride layer has a higher density than the first nitride layer.

3. The method of claim 1, wherein the third nitride layer has a higher density than the second nitride layer.

4. The method of claim 1, wherein the at least part of the third nitride layer diffused through the first and second nitride layers forms a thin film on sidewalls of the two trench nitride layers.

5. The method of claim 1, wherein the first nitride layer is deposited at a faster rate than the second nitride layer.

6. The method of claim 1, wherein the third nitride layer is deposited at a slower rate than the first nitride layer.

7. The method of claim 1, wherein the third nitride layer is deposited at a slower rate than the second nitride layer.

8. The method of claim 1, wherein the first nitride layer has a hydrofluoric acid etching rate higher than that of the second nitride layer.

9. The method of claim 1, wherein the first nitride layer has a hydrofluoric acid etching rate higher than that of the third nitride layer.

10. The method of claim 1, wherein the second nitride layer has a hydrofluoric acid etching rate higher than that of the third nitride layer.

11. A semiconductor manufacturing method comprising:
providing a semiconductor substrate;
forming a cell container contact in the semiconductor substrate;
forming a bit line structure in the semiconductor substrate;
forming a spacer disposed in a trench of the semiconductor substrate, wherein the spacer is sandwiched between the cell container contact and the bit line structure, the spacer comprises two trench nitride layers and an oxide layer sandwiched between the two trench nitride layers;
etching the oxide layer to form an empty gap between the two trench nitride layers;
forming a first nitride layer to cover the empty gap between the two trench nitride layers;
forming a second nitride layer over the first nitride layer, wherein the second nitride layer has a higher density than the first nitride layer; and
using an atomic layer deposition to form a third nitride layer over the second nitride layer, wherein at least part of the third nitride layer diffuses through the first and second nitride layers.

12. The method of claim 11, wherein the bit line structure comprises a bit line cap, a bit line contact and a bit line between the bit line cap dielectric and the bit line contact.

13. The method of claim 11, further comprising forming a landing pad partially embedded in the cell container contact.

14. The method of claim 11, wherein the third nitride layer has a higher density than the first nitride layer or the second nitride layer.

15. The method of claim 11, wherein the at least part of the third nitride layer diffused through the first and second nitride layers forms a thin film on sidewalls of the two trench nitride layers.

16. The method of claim 11, wherein the third nitride layer is deposited at a slower rate than the first nitride layer or the second nitride layer.

17. The method of claim 11, wherein the first nitride layer has a hydrofluoric acid etching rate higher than that of the second nitride layer.

18. The method of claim 11, wherein the second nitride layer has a hydrofluoric acid etching rate higher than that of the third nitride layer.

19. A semiconductor structure comprising:
a semiconductor substrate;
a spacer disposed in a trench of the semiconductor substrate, wherein the spacer comprises two trench nitride layers and an empty gap sandwiched between the two trench nitride layers;
a first nitride layer disposed to cover the empty gap between the two trench nitride layers;
a second nitride layer over the first nitride layer, wherein the second nitride layer has a higher density than the first nitride layer; and
a third nitride layer having a first portion over the second nitride layer and a second portion disposed on sidewalls of the two trench nitride layers.

20. The semiconductor structure of claim 19, wherein the first portion and the second portion of the third nitride layer have the same density.
